(19) United States
(12) Patent Application Publication
(10) Pub. No.: US 2023/0332010 A1
(43) Pub. Date: Oct. 19, 2023

(54) CONFORMAL COATING WITH LOW VOLATILE ORGANIC COMPOUND CONTENT

(71) Applicant: actnano, Inc., Cambridge, MA (US)

(72) Inventors: Irina Mahmad RASID, Somerville, MA (US); Justin KLEINGARTNER, Boston, MA (US); Sruti BALASUBRAMANIAN, Quincy, MA (US)

(21) Appl. No.: 18/299,756

(22) Filed: Apr. 13, 2023

Related U.S. Application Data
(60) Provisional application No. 63/330,464, filed on Apr. 13, 2022.

(51) Int. Cl. C09D 133/08; C09D 5/02; C09D 5/14

(52) U.S. Cl. CPC C09D 133/08; C09D 5/022; C09D 5/14

(57) ABSTRACT

A coating composition comprising at least one film forming component including a water-based carrier, a resin and at least one additive where the coating composition does not contain a high volatile organic compound (VOC) content and the resin is present in an amount sufficient and configured to form a conformal film when applied to a substrate at room temperature is disclosed. A conformal coating, a method of making the coating composition, a method of using the coating composition to protect substrates such as electronic devices including printed circuit board assemblies (PCBAs), from unwanted contaminants. Substrates coated with such conformal coatings are also disclosed.

### TECHNICAL FIELD

The present disclosure generally relates to compositions of low or no volatile organic compound (VOC) content, conformal coating that forms a deformable, insulating film, that is designed to protect a substrate such as an electronic device or a printed circuit board assemblies (PCBAs). The present disclosure also relates to methods of making such compositions protecting substrates such as electronic devices or PCBAs from contaminants by applying the disclosed compositions to desired parts of the substrate such as the printed circuit board of an electronic device. This present disclosure also relates to substrates coated with conformal coatings using the compositions described.

### BACKGROUND

Electronic devices are comprised of electrically conductive components, which can be adversely affected by exposure to harsh environments. Exposure to liquids like water will often lead to corrosion of these components or a short circuit that will eventually destroy the function of the electronic device. In addition, as such devices become more sophisticated with increased functionality, they are being used in more hazardous environments, such as humid environments, environments with corrosive gases, aerosolized or bulk liquids, or conductive particulates that can degrade the functionality of the device.

Electronic devices fail when exposed to these environments since conductive media can provide a pathway for unintended current flow between components that are under bias. Most of these failures manifest as corrosion of electronic components or as a failure of performance of the components. In addition to the components themselves failing, the films formed by conformal coatings can also fail these strenuous conditions due to chemical degradation which may eventually lead to loss of electrical insulation or protection properties.

In addition to environmentally-driven failures, designers of electronic devices and PCBAs are limited by creepage and clearance design requirements, which specify the spacing between electronic components during the design of PCBAs. As modern applications are demanding higher power within the same device footprint or miniaturization of existing designs, electrically insulating coatings can provide a dielectric barrier between electronic components reducing the required creepage and clearance distances.

As a result, durable, electrically-insulating coatings are becoming a more popular form of protection for such devices. Application of traditional coatings requires masking of certain parts to ensure there is no inhibition of the flow of electric current through connectors, test points, or grounding contacts. This process is expensive and time consuming, which adversely affects the overall electronics manufacturing process.

Traditional conformal coatings aim to improve their durability by increasing their mechanical strength. Furthermore, traditional conformal coatings rely on forming heavily crosslinked networks that cannot be deformed easily. This results in a hard and rigid film that requires compromises during the electronics manufacturing process (e.g., masking of or selective coating around certain components). Additionally, some conformal coatings are formulated using coating compositions comprising volatile organic solvents due to these solvents' favorable properties as diluents and carriers. However, these volatile solvents are typically flammable and are hazardous both to the environment and to the operators of coating application equipment.

Accordingly, there is a need for conformal coatings using coating compositions that do not contain a high volatile organic compound (VOC) content to protect electronic devices. There is a need for these coatings to comply with limits set by REACH in the EU and the Blue-Sky initiative in China as well as other regulatory bodies at the national and local levels. For example, in China, GB 30981-2020 sets the standard for allowable VOC content of industrial protective coatings, with the limit for “electrical and electronic product coatings” of the solvent-borne “varnish” type being ≤650 grams per liter (g/L). Additionally, the voluntary standard GB/T 38597-2020 recommends even lower limits of ≤480 g/L for engineering machinery. Other regions, including North America, Europe, and other parts of Asia, are expected to adopt similar if not more stringent restrictions.

There is also a need for methods and uses of such low VOC coatings that allow for the protection of electronic devices from contaminates, for instance, solid particulates including dust, dirt, and metal shavings, as well as liquids, such as water and bodily fluids, including sweat. Furthermore, there is a need for conformal coatings made from such materials that can be applied without the need to mask components prior to coating, such that it can cover an entire printed circuit board, without inhibiting the functionality of the device.

The disclosed coating compositions and deformable low VOC conformal coatings made therefrom are directed to overcoming one or more of the problems set forth above and/or other problems of the prior art.

### SUMMARY

In view of the foregoing, there is disclosed a low VOC composition to protect a substrate from at least one unwanted contaminant. In one embodiment, the disclosed composition comprises at least one film forming component comprising a water-based carrier and at least one additive, where the at least one film forming component comprises a resin present in an amount sufficient and configured to form a conformal film having a glass transition temperature (T_{g}) less than 25° C., when applied to a substrate at room temperature.

There is also disclosed a method of making a low VOC composition for protecting substrates against at least one unwanted contaminant. In one embodiment, the method comprises providing a film forming component comprising a water-based carrier and at least one additive, wherein the at least one film forming component comprises a resin present in an amount sufficient and configured to form a conformal film having a glass transition temperature (T_{g}) less than 25° C. when applied to a substrate at room temperature.

There is also disclosed a method of coating an electronic device with the conformal coating comprising a coating composition that contains a low VOC content or no VOC content, and comprises a film former in a water-based carrier having a glass transition temperature (T_{g}) less than 25° C. In one embodiment, the method of applying such conformal coatings includes spray-coating, film-coating, dip-coating, blade-coating, needle dispensing, rolling, brushing, printing, or jetting.

There is also disclosed a low VOC coating configured to protect a substrate from unwanted contaminants. In one embodiment, the coating is formed on a substrate by using a low VOC composition comprising at least one film forming component comprising a water-based carrier; and at least one additive. In one embodiment, the at least one film forming component comprises a resin present in an amount sufficient and configured to form a conformal film having a glass transition temperature (T_{g}) less than 25° C., when applied to the substrate at room temperature.

There is further disclosed an article or device, such as an electronic device, comprising the conformal coating described herein, as well as methods of applying such coatings. In one embodiment, there is described an electronic device comprising a conformal coating that is deformable and electrically insulating. This conformal coating is formulated with water as the evaporative carrying medium. In such an embodiment, the film forming element has a glass transition temperature (T_{g}) less than 25° C. wherein the film former is deformable and electrically insulating at room temperature.

In one embodiment, there is disclosed a substrate comprising a coating made from the described composition. The substrate includes a coating that comprises a low VOC composition comprising at least one film forming component comprising a water-based carrier; and at least one additive. The at least one film forming component comprises a resin present in an amount sufficient and configured to form a conformal film having a glass transition temperature (T_{g}) less than 25° C., when applied to the substrate at room temperature.

### DETAILED DESCRIPTION

As used herein, “conformal coating” refers to a film that follows the contours of the substrate on which it is applied, such as a printed circuit board or its components, in a continuous fashion without breaks or openings. The conformal coating described herein protects the substrate, such as electronic circuitry, against the environment and liquids or particulates, including water, sweat, or other moisture, dirt, dust, electrically conductive metal particles, metal shavings, and other conductive particulate matter, as well as chemicals.

As used herein, “coating composition” refers to the liquid state material that is applied on to the substrate, such as a printed circuit board or its components, during a coating application process.

As used herein, “waterborne” coating composition refers to a formulation composed of waterborne resins or compounds, additives, and fillers. Waterborne resins or compounds means resins or compounds that have water as the evaporative carrying medium along with other organic solvents. These resins or compounds are either immiscible or insoluble in water and form an emulsion or dispersion when mixed with water. Therefore, when used herein, “waterborne” describes compositions that have water as the main carrying medium.

As used herein, “coalescing agents” refers to organic compounds which aid in the coalescence of particles. In polymer emulsions or dispersions, coalescence of the particles upon application to a substrate is necessary for the formation of a continuous film. For example, in the case of a latex emulsion, the coalescing agents could aid in the coalescence of latex particles into a continuous film. Non-limiting examples of such coalescing agents include benzoates, glycol ethers, and alcohol esters.

As used herein, “film former” refers to a material capable of forming a cohesive, continuous film upon application to a solid surface.

As used herein, “gel” or “gel-state” refers to a material or a composite of materials that form internal networks either due to chemical crosslinking and/or physical association between constituent components. A gel coating exhibits non-Newtonian, viscoelastic, viscoplastic, and/or elastoviscoplastic properties.

As used herein, “deform” or “deformability” refers to the ability of a material to strain (e.g., stretch, bend, etc.) under compressive, tensile, or shear stresses typically incurred during the assembly of electronics or under temperature ranges typically seen during the manufacture and usage of electronics.

As used herein, “flow” or “flowability” refers to the ability of a material to behave like a fluid, which undergoes a steady rate of shearing deformation under the application of a shear stress.

As used herein, a “non-Newtonian fluid,” or versions thereof, means a fluid that does not follow Newton's Law of Viscosity (e.g., a fluid whose viscosity is variable based on applied stress or force). The resulting coating exhibits non-Newtonian behavior that is described by the coating's non-linear relationship between shear stress and shear rate or the presence of yield stress. A non-Newtonian fluid comprises a single- or multi-phase fluid that exhibits non-Newtonian behavior. It may also include single or multiple constituents. The non-Newtonian fluid is sometimes referred to as a complex fluid. In one embodiment, the non-Newtonian fluid is viscoelastic.

As used herein, “viscoelastic” means a material that exhibits both viscous and elastic characteristics when undergoing deformation (i.e., the material both stores energy and dissipates energy during a periodic/cyclic oscillatory shearing deformation). This is commonly reported in terms of non-zero measurable values of both a storage modulus G′ and a loss modulus G″.

As used herein, “viscoplastic” refers to an inelastic behavior of a material in which a material undergoes unrecoverable deformations when a critical load level (known as the yield stress) is reached. The main difference between a viscoplastic and viscoelastic material is the presence of a yield stress. A viscoplastic material has a yield stress below which it will not flow, whereas a viscoelastic material will deform and flow under the application of any finite shear stress.

As used herein, “elastoviscoplastic” refers to a broad class of materials such as the conformal coatings described in this patent which show elastic, viscous, and plastic response characteristics under different levels of applied shear stress or strain. Below a critical stress, often referred to as a yield stress, the material does not undergo steady flow but undergoes a transient deformation in which some strain is accumulated elastically and some energy is dissipated by plastic (irreversible) deformation. When the critical load level is reached (i.e., the yield stress is exceeded) the material begins to flow like a liquid but still exhibits viscoelastic properties (i.e., it has measurable values of the elastic models G′ and loss modulus G″) because some of the initial deformations are stored elastically and some of the external work applied to the material is dissipated viscously. When the applied load is removed this elastoviscoplastic response can be distinguished in a rheometer by a partial (i.e., elastic) recoil or unloading but some irreversible deformation is accumulated due to the plastic nature of the material.

As used herein, “electrical insulation” refers to the property of a material to provide a resistance to electrical flow. For example, in one non-limiting embodiment, when the gel-state coating is applied on an active component which is under bias, the coating provides an electrical resistance greater than 1 kiloohm (kΩ) or a dielectric breakdown voltage greater than 1.5 kilovolt per mil (kV/mil).

As used herein, “glass transition temperature”, T_{g}, refers to the temperature at which an amorphous polymer changes from a hard or glassy state to a soft or rubbery state, or vice versa. For the waterborne resins, the T_{g} specified refers to the T_{g} of the final film that is formed on evaporation of the water.

As used herein, “minimum film formation temperature” denoted as MFFT, refers to the lowest temperature at which an aqueous polymer dispersion or emulsion can coalesce into a thin film when applied onto a substrate.

As used herein, “crosslinking” involves joining two or more polymer chains by chemical or physical associations. “Self-crosslinking resins” refers to ambient cure systems that are supplied as a one-part system and do not require addition of external crosslinkers prior to the application. The crosslinking reaction could be triggered or initiated by different factors. Non-limiting examples of such factors include evaporation of water, change in pH such as a drastic decrease in pH, exposure to UV radiation and combinations thereof.

As used herein, “volatile organic compounds” or “VOCs” are those compounds that have poor water solubility and high vapor pressure. Various governments, regulatory bodies, and non-governmental organizations across the globe have created more specific definitions for VOCs. For example, the WHO defines VOCs as compounds with a boiling point less than 250° C. measured at a standard atmospheric pressure of 101.3 kilo pascals (kPa). In the United States, the United States Environmental Protection Agency (US EPA) defined VOCs as any compound of carbon, excluding carbon monoxide, carbon dioxide, carbonic acid, metallic carbides or carbonates, and ammonium carbonate, which participates in atmospheric photochemical reactions. In China, VOCs are defined as organic chemicals that have a vapor pressure of 0.01 kPa or more at room temperature (20° C.) or organic chemicals susceptible to photoreactions.

As used herein, “low-VOC coatings” refers to coatings that are formed from compositions having a VOC content of 300 g/L or less. The definition of VOCs varies by country and sometimes, even within regions in a country. As used herein, “low-VOC” ranges from no VOC (i.e., 0 g/L) content to less than 300 g/L.

As used herein, “contaminants” refers to unwanted liquids, solids, gases, or combinations thereof. In one embodiment, the contaminants may comprise corrosive gases creating a corrosive environment or solid particulates that can lead to defects in a coating. In another embodiment, the contaminants may comprise water, sweat, or other moisture, dirt, dust, electrically conductive metal particles, metal shavings, and other conductive particulate matter and chemicals, and combinations thereof.

As used herein, “REACH” (Registration, Evaluation, Authorisation and Restriction of Chemicals) is a European Union regulation implemented on Jun. 1, 2007, adopted to improve the protection of human health and the environment from the risks that can be posed by chemicals. It also promotes alternative methods for the hazard assessment of substances in order to reduce the number of tests on animals.

As used herein, the “Blue-Sky Initiative” in China is a three-year action plan for cleaner air, issued by the China's State Council in June 2018, which is a comprehensive strategy to improve air quality through actions across all key sectors. A key objective of the action plan is to reduce emissions of major air pollutants and greenhouse gases and decrease the number of days with high air pollution.

The present disclosure comprises compositions for forming a conformal coating, wherein the conformal coating composition has a low volatile organic compound (VOC) content or no VOC content. The conformal coating composition is waterborne. The low VOC composition includes at least one film forming component. The film forming component includes a water-based carrier and the low VOC composition further includes at least one additive. The at least one film forming component comprises a resin present in an amount sufficient and configured to form a conformal film or coating when applied on a substrate. The conformal coating protects a substrate from at least one unwanted contaminant.

The waterborne conformal coating composition comprises waterborne resins, such as acrylics, styrene-acrylics, silicones, polyurethanes, styrene-butadienes or acrylonitrile-butadienes, and combinations thereof. In one embodiment, the waterborne resins are specifically chosen such that the glass transition temperature (T_{g}) is less than 25° C. This results in a soft film that forms at room temperature on evaporation of water, without the need for volatile organic solvents. In one embodiment, the waterborne resins have a glass transition temperature (T_{g}) ranging from −130° C. to less than 25° C. In another embodiment, the glass transition temperature of the resin ranges from −60° C. to less than 25° C.

The water-based carrier comprises water. In one embodiment, at least one film forming component comprising a water-based carrier comprises an aqueous emulsion or an aqueous dispersion. The aqueous emulsion or the aqueous dispersion may comprise water in an amount ranging from 50 to 70% by weight of the total emulsion or dispersion system.

In one embodiment, the aqueous emulsion or the aqueous dispersion comprises the resin in an amount ranging from 30 to 50% by weight of the total emulsion or dispersion system.

In one embodiment, the composition comprising the water-based carrier does not comprise any volatile organic solvents and is VOC-free. In one embodiment, the composition has a volatile organic content of 100 g/L or less. In another embodiment, the composition has a volatile organic content of 300 g/L or less.

In one embodiment, the conformal film is deformable and electrically insulating when applied on a substrate. When the coating composition is applied on an electric device, the mechanical properties exhibited by the disclosed compositions are designed such that application of the coating over connector pins does not negatively affect the electrical contact resistance between the pins. This may include negligible change to the insertion force required to mate the connectors. In order to connect through the coating, the coating has to be engineered to be ductile enough in the normal, tensile, and compressive directions and exhibit elastoviscoplastic flow properties. The coating could be engineered to demonstrate pencil hardness below 6B. The storage and loss moduli of the coating in the shear, tensile, or compressive directions could be less than 10⁶ Pa at 25° C. when measured at frequencies between 1-100 radian per second (rad/s). The coating could yield when undergoing a stress with a yield stress lower than 10⁴ Pa in the shear, compressive, or tensile directions at 25° C. between 1-100 rad/s.

Films of such low T_{g} (e.g., less than 25° C.) may suffer from excessive tackiness, which may be reduced by blending the low T_{g} resin with an additional resin having a higher T_{g}. The higher T_{g} resin may be of the same or different chemistry as the low T_{g} resin. Additional high T_{g} resin options include alkyd, vinyl acrylic and vinyl-acetate ethylene copolymer. Alternatively, blending with a self-crosslinking resin can also reduce the tackiness of the final coating. These modifications are made without the loss of deformability of the coating composition. In some embodiments, the coating composition may be non-Newtonian and conformable before being applied on a substrate and while being applied on a substrate.

The resins described herein include polymers that have a T_{g}<0° C. For the high T_{g} resins, non-limiting representative examples include alkyd, vinyl acrylic, and vinyl-acetate ethylene copolymer. Coalescence of the high T_{g} resins may be improved by the addition of coalescing solvents to the conformal coating composition, up to 300 g/L.

The waterborne resins described herein include polymer emulsions or dispersions. Suitable polymers are thermoplastics with high molecular weight of 50,000 Daltons or above. The polymers are synthesized to have T_{g} of 25° C. or below.

A variety of polymer chemistries may be employed including acrylics, styrene-acrylics, silicones, polyurethanes, styrene-butadienes, acrylonitrile-butadienes, alkyds, vinyl-acrylics, vinyl-acetate ethylene copolymers and mixtures or copolymers thereof. In some embodiments, polymer emulsions and dispersions may be prepared through polymerization reactions of monomers, oligomers or combinations thereof. Non-limiting examples of monomers which may be used to prepare waterborne resins include acrylic acid, methacrylic acid, methyl acrylate, ethyl acrylate, propyl acrylate, butyl acrylate, pentyl acrylate, hexyl acrylate, 2-ethyl hexyl acrylate, octyl acrylate, nonyl acrylate, decyl acrylate, isobutyl acrylate, lauryl acrylate, methoxyethyl acrylate, ethoxyethyl acrylate, butoxyethyl acrylate and ethoxypropyl acrylate, ethylene, butadiene, propene, butene, isobutene, glycidyl methacrylate, 4-hydroxybutyl acrylate glycidyl ether, hydroxy propyl acrylate, hydroxy butyl acrylate, styrene, alpha-methylstyrene, acrylonitirile, allyl methacrylate, acetoacetyl ethyl methacrylate(AAEM), diacetonea crylamide(DAAM), dimethyl aminomethacrylate, diethylaminomethacrylate, silane containing monomers, diol containing monomers, diisocyanate monomers and mixtures thereof.

In certain embodiments, the polymer emulsions and dispersion may be prepared either through a single stage or multistage process. A multistage process may be used to create particles with a soft and hard phase with different T_{g}, known as “core-shell” particles, or to create interpenetrating networks. Polymer emulsions and dispersions prepared using a single or multistage process may be made using a continuously varied addition of two or more monomers, or using discrete, sequential addition of two or more monomers or mixtures of monomers.

In certain embodiments, the polymer may not show a sharp inflection point corresponding to a single T_{g} when measured by Differential Scanning calorimetry. “Gradient” polymer resins are one example of this phenomenon where there is a change in composition during polymerization. For such polymer resins, the monomers are selected such that the deformability of the resin still meets the requirements outlined in this invention.

In certain embodiments, crosslinkable groups and other additives may be added as part of the mixture of monomers or may be post-added as an additive. Crosslinking may occur by heating, UV exposure, evaporation of water, a drastic drop in pH, or on the addition of crosslinkers prior to application in two-part systems.

During polymerization, a surfactant may be used. A surfactant may be selected from a non-ionic surfactant, an anionic surfactant, a cationic surfactant, and combinations thereof. Non-limiting examples of surfactants that may be used herein may be selected either from non-reactive surfactants or reactive surfactant. Non-limiting examples of such non-reactive surfactants include polyoxyethylene alkyl ether and polyoxyethylene styrenated phenyl ether. Non-limiting examples of such reactive surfactants include surfactants that copolymerize with monomers during polymerization reaction.

In certain embodiments, the emulsion or dispersion may be prepared by emulsion polymerization of the monomers, oligomers, pre-polymers or mixtures thereof.

In certain embodiments, the emulsion or dispersion may be prepared by mechanical emulsification. Nonlimiting examples of mechanical emulsification are high-shear mixing or high-pressure homogenization. In some embodiments, a high-shear mixer or high-pressure homogenizer can be used to create an emulsion from pre-formed polymers, surfactants, carrier fluids (such as water), and combinations thereof. Furthermore, additives or low T_{g} resins can be added to already formed emulsions to enhance their durability or deformability. In some embodiments, the emulsion or dispersion may be prepared by making dispersion of polymers with water and surfactants or other dispersing agents, where the polymers were synthesized through other methods including bulk and solution polymerization.

In one embodiment, the conformal coating compositions may be prepared by low shear mixing of the resins at the desired ratios until a homogenous mixture is obtained. Typical ratios for blending are 50 to 100% by weight of the low T_{g} resin, which could be one or a combination of chemistries, including acrylics, styrene-acrylics, silicones, polyurethanes, styrene-butadienes, acrylonitrile-butadienes. The coating compositions may be applied on the desired substrate and then left to dry at room temperature. Addition of alcohols such as methanol or isopropanol up to 50 g/L may also increase the speed of drying. The use of drying cabinets or other methods to introduce air flow to lower the ambient humidity may be used to increase the speed of drying. Heating in an oven while not required may be used to increase the speed of drying. Additional protection of PCBAs may be achieved with underfilling of components like integrated circuits and ball grid arrays. The drying speed for the coating applied under components could be accelerated by using heat. For printed circuit boards with connector pins, these pins do not need to be masked and the coatings may be applied directly over them, reducing the time and cost of production. Alternative compositions that could give the same results may also include low T_{g} resins where crosslinkers are introduced. In one embodiment, these compositions may be applied as a two-part system if the pot-life of the mixture is limited. In one embodiment, the crosslinking occurs through UV irradiation or through heating.

In one embodiment, the coating composition may be made with one or more additives to further enhance the coating properties. Such additives include fillers, plasticizers, initiators, defoamers, surfactants, antioxidants, hydrophobing agents, biocides, leveling agents, substrate wetting agents, crosslinking agents, dyes, pigments, dispersing agents, passivators, adhesion promoters, coalescing agents or solvents, rheology modifiers, UV absorbers or stabilizers, and anti-corrosion agents. Non-limiting examples of such additives may be found in PCT/US2021/061909, filed on Dec. 3, 2021, which is herein incorporated by reference in its entirety.

In one embodiment, at least one additive is present in the coating composition in an amount ranging from 0.001% to 40% by weight.

In one embodiment, the use of fillers such as fumed silica and fumed alumina may also be used to reduce tackiness of the coating. Examples of such fillers may include functionalized fumed silica, unfunctionalized fumed silica, precipitated silica, silica nanoparticles, alumina nanoparticles, zinc oxide nanoparticles, or cellulose-based particles, and combinations thereof.

In one embodiment, plasticizers are added up to 40% in total composition to soften the film further. In another embodiment, plasticizers are added up to 25%. A plasticizer may be selected from a polymeric plasticizer, a benzoate plasticizer, and a phthalate plasticizer as an additive for the disclosed coating composition. Examples of the benzoate plasticizer may include diethylene glycol dibenzoate, dipropylene glycol dibenzoate, propylene glycol dibenzoate, and combinations thereof. Examples of the polymeric plasticizer may include poly[oxy(methyl-1,2-ethanediyl)], alpha-(methylphenyl)-omega-hydroxy, biobased alkyd, and combinations thereof. In one embodiment, a plasticizer may comprise hydrogenated cycloaliphatic hydrocarbon resins, trimellitates, high molecular weight orthophthalates, silicone oils, octyl epoxy esters or hydrotreated light naphthenic petroleum distillates, and combinations thereof.

In one embodiment, an additive may include an initiator. Examples of such initiators may include difunctional or multifunctional alpha-hydroxyketones, acylphosphine oxides, benzoyl formate, benzophenones, zinc oxide nanoparticles, peroxides, azo compounds, and combinations thereof.

In one embodiment, an additive may include a defoamer. Examples of such a defoamer may include a silicone oil, a mineral oil, a vegetable oil, a polar oil, a molecular defoamer, a hydrophobic nanoparticle, an emulsifier, a solvent, and combinations thereof.

In one embodiment, an additive may include a molecular defoamer, such as a Gemini surfactant which has a dimeric structure, composed of two hydrophobic chains and two hydrophilic heads, linked by a spacer at or near the headgroups. In addition to the chemistries listed above, waterborne epoxy systems may be designed such that the film formed is deformable by reducing the extent of crosslinking in the system.

In one embodiment, an additive may include a hydrophobing agent comprising paraffin wax emulsions, modified paraffin waxes, paraffin/polyethylene wax emulsions, silicone resins, and combinations thereof.

In one embodiment, an additive may include a biocide agent comprising an isothiazolinone, formaldehyde-releasing biocides (FA-R), fungicides comprising carbamates, and combinations thereof.

In one embodiment, an additive may include a rheology modifier comprising a hydrophobic modified ethoxylated urethane (HEUR) type thickener, an alkali swellable emulsion, an acrylic copolymer, and combinations thereof.

In one embodiment, an additive may include a leveling agent comprising modified silicones, fluorosurfactants, and combinations thereof. In other embodiment, the leveling agent may comprise silicones, liquid polyacrylates, ionic surfactants, non-ionic surfactants, and combinations thereof.

In one embodiment, an additive may include a substrate wetting agent comprising a siloxane, a multifunctional surfactant, a polyglycol ether, a modified polyglycol ether, and combinations thereof.

In one embodiment, an additive may include dyes comprising a stilbene compound, a distyryl biphenyl derivative, a benzoxazole, and combinations thereof. In one embodiment, an additive may include a crosslinking agent. The crosslinking agent may comprise zinc ammonium carbonate solution, carbodiimide crosslinkers, melamine crosslinkers, aziridine crosslinkers, mono- or multi-functional, aliphatic, glycerol polyglycidyl ether-based crosslinkers, mono- or multi-functional aliphatic epoxies, ethylene glycol diglycidyl ethers, oxazoline reactive polymers, polyols, polyisocyanates, methylacrylamide, a dihydrazide crosslinkers, organofunctional silanes, metal complexes, UV-vulnerable functional monomers, and combinations thereof.

In one embodiment, an additive may include a pigment. The pigment may comprise organic or inorganic pigments and combinations thereof. In further embodiments, the organic and inorganic pigments may comprise a borophosphate, a borosilicate, a phosphate, and a phosphosilicate, a color pigment and dye comprising an inorganic pigment, an organic pigment, and a dispersion of a pigment and dispersant, carbon black, a special effect pigment, titanium dioxide, and combinations thereof. In an alternate embodiment, the pigment may be added to impart color, or function including anti-corrosion properties.

In one embodiment, an additive may include a dispersing agent. The dispersing agent may comprise a fatty acid-modified polyester, sodium salt of an acrylic polymer, an ammonium salt of a hydrophobic copolymer, a modified polyacrylate, and combinations thereof.

In one embodiment, an additive may include an adhesion promoter. The adhesion promoter may comprise a silane, an ethylene copolymer, a hydroxyl functional copolymer, and combinations thereof.

In one embodiment, an additive may include a coalescing agent comprising a glycol ether, an ester alcohol, and combinations thereof. In one embodiment, high boiling point coalescing solvents, with a boiling point of 250° C. and above, may be used such that the solvent will slowly evaporate over time; for example, over minutes, over hours, or over days. The coalescing solvents in this case act as a temporary plasticizer, which may soften the film to make it deformable. Once the solvent has fully evaporated, the film will harden. This is advantageous for applications where deformability is desirable in the first few days following the coating process, but a harder film may provide more robust protection in the field.

In one embodiment, an additive may include a UV absorber or stabilizer comprising hydroxy-phenyl-benzo-triazoles, hydroxy-phenyl-triazines, hydroxy-benzophenones, sterically hindered amines, and combinations thereof.

In one embodiment, an additive may include an anti-corrosion agent comprising an organic acid amine complex, a zinc phosphate, and combinations thereof.

In one embodiment, an additive may include an antioxidant comprising a phenolic antioxidant, an amine antioxidant, a thioether antioxidant, a phosphite antioxidant, a lactone, and combinations thereof.

In one embodiment, the antioxidant may be selected from phenolic antioxidants including benzenepropanoic acid, 3,5-bis(1,1-dimethylethyl)-4-hydroxy-, octadecyl ester; benzenepropanoic acid, 3,5-bis(1,1-dimethylethyl)-4-hydroxy-,2,2-bis[[3-[3,5-bis(1,1-dimethylethyl)-4-hydroxyphenyl]-1-oxopropoxy]methyl]-1,3-propanediyl ester; reaction mass of isomers of: C7-9-alkyl 3-(3,5-di-tert-butyl-4-hydroxyphenyl) propionate; 1,3,5-triazine-2,4,6(1H,3H,5H)-trione, 1,3,5-tris {[3,5-bis(1,1-dimethylethyl)-4-hydroxyphenyl] methyl}-; benzenepropanoic acid, 3-(1,1-dimethylethyl)-4-hydroxy-5-methyl-, 2,4,8,10-tetraoxaspiro [5.5]undecane-3,9-diylbis(2,2-dimethyl-2,1-ethanediyl) ester; or phenol, 4-methyl-, reaction products with dicyclopentadiene and isobutylene; and combinations thereof. In one embodiment, the amine antioxidants may be selected from benzenamine, N-phenyl-, reaction products with 2,4,4-trimethylpentene; 1-Naphthalenamine, N-phenyl-ar-(1,1,3,3-tetramethylbutyl); 4,4′-Dioctyldiphenylamin; other alkylated amines, and combinations thereof. In one embodiment, the thioether antioxidants may be selected from propanoic acid, 3-(dodecylthio)-,1,1′-[2,2-bis[[3-(dodecylthio)-1-oxopropoxy]methyl]-1,3-propanediyl] ester; or propanoic acid, 3,3′-thiobis-, 1,1′-ditridecyl ester; and combinations thereof. In one embodiment, the phosphite antioxidants may be selected from tris(2,4-di-tert-butylphenyl) phosphite; butylidenebis[2-tert-butyl-5-methyl-p-phenylene]-P,P,P′,P′-tetratridecylbis(phosphine); 12H-Dibenzo[d,g][1,3,2]dioxaphosphocin,2,4,8,10-tetrakis(1,1-dimethylethyl)-6-[(2-ethylhexyl)oxy]-; and combinations thereof.

In one embodiment, an additive may include passivators. Such passivators may include a hydrazide or a triazole, selected from dodecanedioic acid, 1,12-bis[2-(2-hydroxybenzoyl)hydrazide]; benzenepropanoic acid, 3,5-bis(1,1-dimethylethyl)-4-hydroxy-, 2-[3-[3,5-bis(1,1-dimethylethyl)-4-hydroxyphenyl]-1-oxopropyl]hydrazide; 1,2,4-Triazole, 2-Hydroxy-N-(1H-1,2,4-triazol-3-yl)benzamide; 1H-Benzotriazole-1-methanamine, N,N-bis(2-ethylhexyl)-ar-methyl-; 1H-1,2,4-Triazole-1-methanamine, N,N-bis(2-ethylhexyl)-; and combinations thereof.

In one embodiment, an additive may include rheology modifiers comprising sodium polyacrylates, polyamide wax, polyethylene wax, hydrogenated castor oils, attapulgite clay, fumed silica, precipitated silica, metal-oxide particles, and combinations thereof.

In one embodiment, an additive may include adhesion promoters comprising chlorinated polyolefins, cyanoacrylate primers, polyester alkyl ammonium salts, aminofunctional polyethers, maleic anhydride, carboxylated polypropylene, glycidylmethacrylate-functionalized polyolefins, trimethoxyvinylsilane, silanes, and combinations thereof.

In one embodiment, an additive may include a substrate wetting or dispersing agent. Examples of such substrate wetting or dispersing agent may include alkylammonium salts of a polycarboxylic acid, alkylammonium salt of an acidic polymer, salt of unsaturated polyamine amides and acidic polyesters, maleic anhydride functionalized ethylene butyl acrylate copolymer, other ionic or non-ionic surfactants, and combinations thereof.

In one embodiment, an additive may include a tackifier comprising hydrogenated hydrocarbon resins, cycloaliphatic hydrocarbon resins, and combinations thereof.

In one embodiment, a method of making a low VOC composition for protecting substrates against at least one unwanted contaminant may include providing a film forming component and at least one additive. The film forming component may comprise a water-based carrier. The at least one film forming component may comprise a resin present in an amount sufficient and configured to form a conformal film having a glass transition temperature (T_{g}) less than 25° C., when applied to a substrate at room temperature.

In one embodiment, providing the film forming component for the method of making the low VOC composition may include at least one polymerization step. The at least one polymerization step may include reacting at least one monomer, oligomer, or pre-polymer to produce a film forming polymer resin that can be dispersed or suspended in a water-based carrier with at least one additive to form the low VOC composition. The monomer, oligomer or prepolymer may contain one or multiple functional groups capable of participating in the polymerization reaction.

In one embodiment, the polymerization step may proceed by addition or condensation polymerization or combinations thereof.

In one embodiment, the polymerization step may occur after the at least one monomer, oligomer or pre-polymer has been dispersed or suspended in the water-based carrier. The polymerization step may produce reaction products that are then dispersed or suspended in the water-based carrier.

In one embodiment, the method of making the conformal coating composition may produce one or more of the following by-products: water, ammonia, and a compound created by a condensation reaction.

In one embodiment, at least one additive could be added to the polymerization reaction or post-added to the reaction product. The addition of the monomers, oligomers or pre-polymers can be done in a single or multistage process. For example, the addition of the monomers, oligomers or pre-polymers can be made using a continuously varied addition of two or more monomers, or using discrete, sequential addition of two or more monomers or mixtures of monomers.

In one embodiment, a method of coating a substrate may include coating the substrate with a low VOC conformal coating composition. The conformal coating composition may comprise at least one film forming component comprising a water-based carrier; and at least one additive. The at least one film forming component may comprise a resin present in an amount sufficient and configured to form the conformal film having a glass transition temperature (T_{g}) less than 25° C., when applied to a substrate at room temperature.

The coating may be applied on the substrate using several techniques. Non-limiting examples of such techniques may include atomized or non-atomized spraying spray-coating, needle dispensing, dipping, jetting, blade coating, brush coating, inkjet printing, crosslinking through UV radiation, crosslinking through heating, crosslinking using humidity or combinations thereof.

In one embodiment, the coating composition may exist as a multi-part system, each with a subset of components, wherein each of the multi-part system can be successively or simultaneously applied to the substrate to form the conformal coating.

In one embodiment, there may be an intermediate stage once the coating composition is applied on a substrate and the carrying medium evaporates to leave the coating behind. In some embodiments, the coating composition at this intermediate stage may have residual amount of the evaporative carrying medium. In some embodiments, this evaporative carrying medium could be water, coalescing solvent, alcohol, pH neutralizer, or combinations thereof.

In one embodiment, the substrate is an electronic device. The coating may cover male, female, or both components of connectors in the electronic device without adversely affecting the electrical properties of the printed circuit board.

In one embodiment, the coating may have a lubricating effect and reduce the force required to insert and mate connectors when applied on the substrate. In another embodiment, the substrate is partially coated or coated in its entirety. Furthermore, when the coating is applied on a printed circuit board, the coating may be deposited on different components of the printed circuit board based on desired environmental protection.

In one embodiment, the coating may be deposited on the substrate to achieve a film thickness ranging from 25 nanometers (nm) to 500 micrometers (μm). When the coating composition is applied on the substrate to form a conformal coating, at least one component in the coating composition may evaporate to render the coating deformable during evaporation and non-deformable after evaporation. In one embodiment, one of the components in the coating may crosslink to render the coating deformable during crosslinking and non-deformable after crosslinking.

In one embodiment, when applied as a coating, the conformal coating may range in thickness from 25 nm to 500 μm, such as 50 nm to 100 μm, such as 1 μm to 200 μm, such as 10 μm to 500 μm. In some embodiments, the coating may conform to the substrate morphologies with length-scales lower than 1 μm, such as 100 nm to less than 1 μm to protect the substrate from unwanted contaminants. Examples of unwanted contaminants may include but are not limited to liquids, particulates, corrosive environments, and combinations thereof. In one embodiment, an unwanted contaminant may be any one from water, sweat, or other moisture, dirt, dust, electrically conductive metal particles, metal shavings, and other conductive particulate matter and chemicals, and combinations thereof.

Coating thickness may be measured by non-destructive optical techniques, such as ellipsometry, spectral reflectance techniques, such as interferometry, and confocal microscopy. A non-limiting example of such non-destructive method to measure coating thickness include SEM. Traditional coatings, such as conformal and vacuum coatings, are typically much thicker than the thickness of the disclosed coating. For example, traditional coatings typically range in thickness from up to hundreds of microns, which may impede both the radio frequency and Wi-Fi transmission of the electronic device, and further act as a thermal insulator. The thinner thickness range of a gel-state coating does not adversely affect the functionality of an electronic device and can have a negligible thermal impact on the device. A non-limiting example of a functioning electronic device is a fully assembled printed circuit board. A fully assembled printed circuit board with a gel-state coating will exhibit normal radio frequency performance, normal thermal properties, and other normal functionalities.

### Measurement Techniques

Following the application of a coating to an electronic device, the various properties may be measured in the following manners.

The hydrophobicity or hydrophilicity of a coating may be measured by observing the contact angle a water droplet makes on the surface of the coating. The oleophobicity or oleophilicity of a coating may be measured by observing the contact angle a droplet of hexadecane makes on the surface of the coating.

The electrical insulation of a coating may also be determined by measuring the dielectric withstanding voltage on a coated circuit board. A continuously increasing voltage may be applied on the coated circuit board, and the voltage at which the current arcs through to air may be determined. This voltage is a measure of the effectiveness of the coating.

The electrical insulation of a coating may also be determined by measuring a material electrical property of the coating, such as the loss tangent or the dielectric constant using a network analyzer.

The non-Newtonian, viscoelastic, viscoplastic, and elastoviscoplastic nature of the coating may be measured by looking at various properties. The response of the coating to an applied stress or strain may be measured using a rheometer to study the deformation of the coating. The viscoelastic moduli may be measured using a Small Angle Oscillatory Stress sweep, and the yield stress and high shear viscosity may be measured using a stress sweep. The degree of deformation may also be measured by quantifying hardness, modulus, tack, failure strain, creep, and ductility in tensile, compressive, and shear directions.

The features and advantages of the compositions, coatings, and methods disclosed herein are illustrated by the following examples, which are not to be construed as limiting the scope of the present disclosure in any way.

### EXAMPLES

Conformal coating compositions were prepared by low shear mixing of the resins at the desired ratios until a homogenous mixture was obtained. Coating compositions were applied by spray coating or blade coating on the desired substrate and then dried under ambient conditions, unless otherwise stated. The invention is illustrated by the following examples.

### Working Example 1

In this example, 10 g of an acrylic emulsion (T_{g}: −42° C., 50% solids, pH: 7.7 to 8.2) was charged into a beaker. Under low shear mixing, 0.005 g of an adhesion promoter and 0.005 g of a UV dye were added. The pH was monitored throughout the mixing process, and a neutralizer was added to maintain the pH between 7.7 to 8.2.

### Working Example 2

In this example, 10 g of an acrylic emulsion (T_{g}: −42° C., 50% solids by weight, pH: 7.7 to 8.2) was charged into a beaker. Under low shear mixing, 0.035 g of a bactericide and 0.25 g of a fungicide, and 0.005 g of a UV dye were added. The pH was monitored throughout the mixing process, and a neutralizer was added to maintain the pH between 7.7 to 8.2.

### Working Example 3

In this example, 8 g of an acrylic emulsion (T_{g}: −42° C., 50% solids, pH: 7.7 to 8.2) and 2 g of a self-crosslinking styrene acrylic emulsion (T_{g}: 23° C., 43% solids by weight, pH: 7.7-8.2) was charged into a beaker. Under low shear mixing, 0.005 g of a UV dye was added. The pH was monitored throughout the mixing process, and a neutralizer was added to maintain the pH between 7.7 to 8.2.

### Working Example 4

In this example, 9 g of a self-crosslinking styrene-acrylic emulsion (minimum film forming temperature: 8-12° C., 48% solids, pH: 8.5-9.0) was charged into a beaker. Under low shear mixing, 2 g of deionized water, 0.05 g of a substrate wetting agent, 0.005 g of a UV dye, 0.04 g of a bactericide, 0.1 of fungicide, 0.1 g of a surfactant and 1 g of plasticizer were added. The pH was monitored throughout the mixing process, and a neutralizer was added to maintain the pH between 8.5 to 9.0.

### Working Example 5

In this example, 9 g of a self-crosslinking styrene-acrylic emulsion (minimum film forming temperature: 8-12° C., 48% solids by weight, pH: 8.5-9.0) was charged into a beaker. Under low shear mixing, 1.24 g of deionized water, 0.005 g of a UV dye, 0.25 g of a coalescing solvent, 0.05 g of a defoamer, and 1 g of plasticizer were added. The pH was monitored throughout the mixing process, and a neutralizer was added to maintain the pH between 8.5 to 9.0.

### Working Example 6

In this example, 9 g of an acrylic emulsion (T_{g}: 7° C., 57% solids by weight, pH: 7.5 to 9.5) was charged into a beaker. Under low shear mixing, 1 g of a coalescing solvent (boiling point: 274° C.), 3 g of deionized water, and 0.005 g of a UV dye were added. The pH was monitored throughout the mixing process, and a neutralizer was added to maintain the pH between 7.5 to 9.5.

### Working Example 7

In this example, 8.5 g of an acrylic emulsion (T_{g}: 7° C., 57% solids by weight, pH: 7.5 to 9.5) was charged into a beaker. Under low shear mixing, 2.25 g of deionized water, 0.05 g of a substrate wetting agent, 0.005 g of a UV dye, 0.04 g of a bactericide, 0.1 of fungicide, and 1.5 g of plasticizer were added. The pH was monitored throughout the mixing process, and a neutralizer was added to maintain the pH between 7.5 to 9.5.

### Working Example 8

In this example, 9.5 g of an acrylic emulsion (T_{g}: −42° C., 50% solids by weight, pH: 7.7 to 8.2) was charged into a beaker. Under low shear mixing, 0.5 g of a hydrophobic fumed silica dispersion (pre-dispersed in water at 20% solids by weight) and 0.005 g of a UV dye were added. The pH was monitored throughout the mixing process, and a neutralizer was added to maintain the pH between 7.7 to 8.2.

### Working Example 9

In this example, 8.5 g of an acrylic emulsion (T_{g}: 7° C., 57% solids by weight, pH: 7.5 to 9.5) was charged into a beaker. Under low shear mixing, 2.25 g of deionized water, 0.05 g of a substrate wetting agent, 0.005 g of a UV dye, 0.015 g of a leveling agent and 1.5 g of plasticizer were added. The pH was monitored throughout the mixing process, and a neutralizer was added to maintain the pH between 7.5 to 9.5.

### Working Example 10

In this example, 8.5 g of an acrylic emulsion (T_{g}: 7° C., 57% solids by weight, pH: 7.5 to 9.5) was charged into a beaker. Under low shear mixing, 2.25 g of deionized water, 0.05 g of a substrate wetting agent, 0.005 g of a UV dye, 0.02 g of a rheology modifier, and 1.5 g of plasticizer were added. The pH was monitored throughout the mixing process, and a neutralizer was added to maintain the pH between 7.5 to 9.5.

### Working Example 11

In this example, 9 g of an acrylic emulsion (T_{g}: −42° C., 50% solids by weight, pH: 7.7 to 8.2) and 1 g of a silicone emulsion (T_{g}: −41° C., 45% solids by weight, pH: 11) was charged into a beaker. Under low shear mixing, 0.005 g of a UV dye was added. The pH was monitored throughout the mixing process, and a neutralizer was added to maintain the pH between 7.7 to 8.2.

### Working Example 12

In this example, 9.6 g of an acrylic emulsion (T_{g}: −42° C., 50% solids by weight, pH: 7.7 to 8.2) and 0.4 g of a paraffin-based wax emulsion (50% solids by weight) was charged into a beaker. Under low shear mixing, 0.005 g of a UV dye was added. The pH was monitored throughout the mixing process, and a neutralizer was added to maintain the pH between 7.7 to 8.2.

### Working example 13

In this example, 10 g of an acrylic emulsion (T_{g}: −42° C., 50% solids by weight, pH: 7.7 to 8.2) and 0.1 g of a crosslinking agent (pre-dissolved in solution at 15% solids by weight) was charged into a beaker. Under low shear mixing, 0.005 g of a UV dye was added. The pH was monitored throughout the mixing process, and a neutralizer was added to maintain the pH between 7.7 to 8.2.

### INDUSTRIAL APPLICABILITY

This present disclosure describes conformal coatings formulated as waterborne coatings that are low-VOC or VOC-free that are designed to protect a substrate, such as an electronic device, or printed circuit board assemblies (PCBAs) from unwanted contaminants. In particular, the present disclosure is useful for manufacturers that seek protection against moisture with stringent VOC requirements or those who would like to reduce the need for fume extraction and flammable storage would benefit from the invention. This includes electrical insulation for printed circuit board manufacturers and general protection against moisture for non-electrical devices/components where exposure to water may lead to water-induced damage such as corrosion, discoloration, or blemishes. In addition to performance benefits, the low-VOC or VOC-free coatings may reduce overall manufacturing costs and reduce the environmental impact of using conformal coatings.

Thus, in one embodiment, the utility of this invention is to protect circuit boards from exposure to water or other harmful environmental elements while allowing for modifications to the PCBA following assembly, either during the manufacturing process or product maintenance. These modifications may include functional board connections or rework of faulty board components through the disclosed conformal coating. The disclosed conformal coating is also advantageous in accommodating thermal expansion or contraction of the PCBA without contributing additional mechanical stress.

In another embodiment, the surface may comprise a metal and the unwanted environment is corrosive and aqueous, such as condensation, tap water, sweat, sebum, salt water, carbonated beverages, coffee, liquid coolant or antifreeze. In one embodiment, the surface comprises a metal that exhibits galvanic corrosion and the unwanted environment causes galvanic corrosion. More generally, the surface may comprise any metal that could undergo oxidation or other adverse chemical reactions due to the corrosive environment.

The conformal coating may exhibit viscoeleastic, viscoplastic, or elasto-visco-plastic properties once the water evaporates upon application to form a continuous film.

The conformal coating may also have a thickness ranging from 25 nm to 500 μm when applied on various surfaces.

The conformal coating may conform to features less than 25 nm in length scale and protect from corrosive environments.

In one embodiment, the composition exhibits electrical insulation properties, such that they prevent current leakage or arcing between two metal contacts when the composition is placed between said metal contacts. The electrical insulating properties may also prevent flowing current from active electronics on a printed circuit board to conductive media or environments or prevent electrostatic discharge from a charge carrier to active electronics on a printed circuit board. In one embodiment, the coating composition may be applied on automotive parts to form a conformal coating to protect from unwanted contaminants.

There is described herein a low VOC composition to protect a substrate from at least one unwanted contaminant, comprising: at least one film forming component comprising a water-based carrier; and at least one additive, wherein the at least one film forming component comprises a resin present in an amount sufficient and configured to form a conformal film having a glass transition temperature (T_{g}) less than 25° C., when applied to a substrate at room temperature.

In one embodiment, in the low VOC composition described herein, the conformal film is deformable and electrically insulating when being applied on the substrate.

In one embodiment, in the low VOC composition described herein the at least one additive comprises fillers, plasticizers, initiators, defoamers, surfactants, antioxidants, hydrophobing agents, biocides, leveling agents, substrate wetting agents, crosslinking agents, dyes, pigments, dispersing agents, passivators, adhesion promoters, coalescing agents or solvents, rheology modifiers, UV absorbers or stabilizers, and anti-corrosion agents.

In one embodiment, in the low VOC composition described herein the at least one additive is present in the composition in an amount ranging from 0.001% to 40% by weight.

In one embodiment, the fillers comprise functionalized fumed silica, unfunctionalized fumed silica, precipitated silica, silica nanoparticles, alumina nanoparticles, zinc oxide nanoparticles, or cellulose-based particles, and combinations thereof.

In one embodiment, the plasticizers comprise a polymeric plasticizer, a benzoate plasticizer, and a phthalate plasticizer.

In one embodiment, the benzoate plasticizer comprises diethylene glycol dibenzoate, dipropylene glycol dibenzoate, propylene glycol dibenzoate, and combinations thereof.

In one embodiment, the polymeric plasticizer comprises poly[oxy(methyl-1,2-ethanediyl)], alpha-(methylphenyl)-omega-hydroxy, biobased alkyd, and combinations thereof.

In one embodiment, the plasticizer comprises hydrogenated cycloaliphatic hydrocarbon resins, trimellitates, high molecular weight orthophthalates, silicone oils, octyl epoxy esters or hydrotreated light naphthenic petroleum distillates, and combinations thereof.

In one embodiment, the initiator comprises a difunctional or multifunctional alpha-hydroxyketones, acylphosphine oxides, benzoyl formate, benzophenones, zinc oxide nanoparticles, peroxides, azo compounds, and combinations thereof.

In one embodiment, the defoamer comprises a silicone oil, a mineral oil, a vegetable oil, a polar oil, a molecular defoamer, a hydrophobic nanoparticle, an emulsifier, a solvent, and combinations thereof.

In one embodiment, the surfactant comprises a non-ionic surfactant, anionic surfactant, cationic surfactant, zwitterionic surfactants, and combinations thereof.

In one embodiment, the hydrophobing agent comprises paraffin wax emulsions, modified paraffin waxes, paraffin/polyethylene wax emulsions, silicone resins, and combinations thereof.

In one embodiment, the biocide agent comprises an isothiazolinone, formaldehyde-releasing biocides (FA-R), fungicides comprising carbamates, and combinations thereof.

In one embodiment, the rheology modifier comprises a hydrophobic modified ethoxylated urethane (HEUR) type thickener, an alkali swellable emulsion, an acrylic copolymer, and combinations thereof.

In one embodiment, the leveling agents comprise silicones, liquid polyacrylates, ionic surfactants, non-ionic surfactants, fluorosurfactants and combinations thereof.

In one embodiment, the substrate wetting agent comprises a siloxane, a multifunctional surfactant, a polyglycol ether, a modified polyglycol ether, and combinations thereof.

In one embodiment, the dyes comprise a stilbene compound, a distyryl biphenyl derivative, a benzoxazole, and combinations thereof.

In one embodiment, the crosslinking agent comprises zinc ammonium carbonate solution, carbodiimide crosslinkers, melamine crosslinkers, aziridine crosslinkers, mono- or multi-functional, aliphatic, glycerol polyglycidyl ether-based crosslinkers, mono- or multi-functional aliphatic epoxies, ethylene glycol diglycidyl ethers, oxazoline reactive polymers, polyols, polyisocyanates, methylacrylamide, a dihydrazide crosslinkers, organofunctional silanes, metal complexes, UV-vulnerable functional monomers, and combinations thereof.

In one embodiment, the pigment comprises a borophosphate, a borosilicate, a phosphate, and a phosphosilicate, a color pigment and dye comprising an inorganic pigment, an organic pigment, and a dispersion of a pigment and dispersant, an extender, carbon black, a special effect pigment, titanium dioxide, and combinations thereof.

In one embodiment, the dispersing agent comprises a fatty acid-modified polyester, sodium salt of an acrylic polymer, an ammonium salt of a hydrophobic copolymer, a modified polyacrylate, zwitterionic surfactant, and combinations thereof.

In one embodiment, the adhesion promoter comprises a silane, an ethylene copolymer, a hydroxyl functional copolymer, and combinations thereof.

In one embodiment, the coalescing agent comprises a glycol ether, an ester alcohol, and combinations thereof.

In one embodiment, the UV absorber or stabilizer comprises hydroxy-phenyl-benzo-triazoles, hydroxy-phenyl-triazines, hydroxy-benzophenones, sterically hindered amines, and combinations thereof.

In one embodiment, the anti-corrosion agent comprises an organic acid amine complex, a zinc phosphate, and combinations thereof.

In one embodiment, the antioxidant comprises a phenolic antioxidant, an amine antioxidant, a thioether antioxidant, a phosphite antioxidant, a lactone, and combinations thereof.

In one embodiment, the phenolic antioxidants are selected from benzenepropanoic acid, 3,5-bis(1,1-dimethylethyl)-4-hydroxy-, octadecyl ester; benzenepropanoic acid, 3,5-bis(1,1-dimethylethyl)-4-hydroxy-,2,2-bis[[3-[3,5-bis(1,1-dimethylethyl)-4-hydroxyphenyl]-1-oxopropoxy]methyl]-1,3-propanediyl ester; reaction mass of isomers of: C7-9-alkyl 3-(3,5-di-tert-butyl-4-hydroxyphenyl) propionate; 1,3,5-triazine-2,4,6(1H,3H,5H)-trione, 1,3,5-tris {[3,5-bis(1,1-dimethylethyl)-4-hydroxyphenyl] methyl}-; benzenepropanoic acid, 3-(1,1-dimethylethyl)-4-hydroxy-5-methyl-, 2,4,8,10-tetraoxaspiro [5.5]undecane-3,9-diylbis(2,2-dimethyl-2,1-ethanediyl) ester; or phenol, 4-methyl-, reaction products with dicyclopentadiene and isobutylene; and combinations thereof.

In one embodiment, the amine antioxidants are selected from benzenamine, N-phenyl-, reaction products with 2,4,4-trimethylpentene; 1-Naphthalenamine, N-phenyl-ar-(1,1,3,3-tetramethylbutyl); 4,4′-dioctyldiphenylamine; other alkylated amines, and combinations thereof.

In one embodiment, the thioether antioxidants are selected from propanoic acid, 3-(dodecylthio)-,1,1′-[2,2-bis[[3-(dodecylthio)-1-oxopropoxy]methyl]-1,3-propanediyl] ester; or propanoic acid, 3,3′-thiobis-, 1,1′-ditridecyl ester; and combinations thereof.

In one embodiment, the phosphite antioxidants are selected from tris(2,4-di-tert-butylphenyl) phosphite; butylidenebis[2-tert-butyl-5-methyl-p-phenylene]-P,P,P′,P′-tetratridecylbis(phosphine); 12H-Dibenzo[d,g][1,3,2]dioxaphosphocin,2,4,8,10-tetrakis(1,1-dimethylethyl)-6-[(2-ethylhexyl)oxy]-; and combinations thereof.

In one embodiment, the passivators comprise a hydrazide or a triazole, selected from dodecanedioic acid, 1,12-bis[2-(2-hydroxybenzoyl)hydrazide]; benzenepropanoic acid, 3,5-bis(1,1-dimethylethyl)-4-hydroxy-, 2-[3-[3,5-bis(1,1-dimethylethyl)-4-hydroxyphenyl]-1-oxopropyl]hydrazide; 1,2,4-Triazole, 2-Hydroxy-N-(1H-1,2,4-triazol-3-yl)benzamide; 1H-Benzotriazole-1-methanamine, N,N-bis(2-ethylhexyl)-ar-methyl-; 1H-1,2,4-Triazole-1-methanamine, N, N-bis(2-ethylhexyl)-; and combinations thereof.

In one embodiment, the rheology modifier comprises sodium polyacrylates, polyamide wax, polyethylene wax, hydrogenated castor oils, attapulgite clay, fumed silica, precipitated silica, metal-oxide particles, and combinations thereof.

In one embodiment, the adhesion promoter comprises chlorinated polyolefins, cyanoacrylate primers, polyester alkyl ammonium salts, aminofunctional polyethers, maleic anhydride, carboxylated polypropylene, glycidylmethacrylate-functionalized polyolefins, trimethoxyvinylsilane, silanes, and combinations thereof.

In one embodiment, the substrate wetting or dispersing agent comprises alkylammonium salts of a polycarboxylic acid, alkylammonium salt of an acidic polymer, salt of unsaturated polyamine amides and acidic polyesters, maleic anhydride functionalized ethylene butyl acrylate copolymer, other ionic or non-ionic surfactants, and combinations thereof.

In one embodiment, the tackifier comprises hydrogenated hydrocarbon resins, cycloaliphatic hydrocarbon resins, and combinations thereof.

In one embodiment, the conformal film has a thickness ranging from 25 nm to 500 μm,

In one embodiment, the at least one film forming component comprising a water-based carrier comprises an aqueous emulsion or an aqueous dispersion.

In one embodiment, the aqueous emulsion or the aqueous dispersion comprises water in an amount ranging from 50 to 70% by weight.

In one embodiment, the aqueous emulsion or the aqueous dispersion comprises the resin in an amount ranging from 30 to 50% by weight.

In one embodiment, the water-based carrier does not comprise any volatile organic solvents and is VOC-free.

In one embodiment, the resin is selected from acrylics, styrene-acrylics, silicone, polyurethane, styrene-butadiene, acrylonitrile-butadiene, and combinations thereof.

In one embodiment, the composition further comprises an additional resin that has a higher T_{g} than the first resin.

In one embodiment, the additional resin has the same or different chemistry than the first resin.

In one embodiment, the additional resin comprises an alkyd, vinyl acrylic, or vinyl-acetate ethylene copolymer.

In one embodiment, the at least one film forming component comprises a blend of the resin and a self-cross-linking resin.

In one embodiment, the composition comprises a plasticizer in an amount up to 40% by weight.

In one embodiment, the composition has a volatile organic content of 100 g/L or less.

In one embodiment, the composition has no volatile organic content.

In one embodiment, the at least one unwanted contaminant comprises one or more liquids, particulates, corrosive environments, and combinations thereof.

In one embodiment, the at least one unwanted contaminant comprises water, sweat, or other moisture, dirt, dust, electrically conductive metal particles, metal shavings, and other conductive particulate matter and chemicals, and combinations thereof.

There is also described herein a method of making a low VOC composition described herein and summarized above, for protecting substrates against at least one unwanted contaminant, the method comprising: providing a film forming component comprising a water-based carrier; and combining at least one additive with said film forming component comprising a water-based carrier, wherein the at least one film forming component comprises a resin present in an amount sufficient and configured to form a conformal film having a glass transition temperature (T_{g}) less than 25° C., when applied to a substrate at room temperature.

In one embodiment, providing the film forming component comprises at least one polymerization step comprising reacting at least one monomer, oligomer, or pre-polymer to produce a film forming polymer resin that can be dispersed, or suspended in a water-based carrier with at least one additive to form the low VOC composition.

In one embodiment, the monomer, oligomer, or prepolymer contains one or multiple functional groups capable of participating in the polymerization reaction.

In one embodiment, the polymerization step proceeds by addition or condensation polymerization or combinations thereof.

In one embodiment, the polymerization step occurs after the at least one monomer, oligomer, or pre-polymer has been dispersed or suspended in the water-based carrier.

In one embodiment, the polymerization step produces reaction products that are then dispersed or suspended in the water-based carrier.

In one embodiment, the method produces one or more of the following by-products: water, ammonia, and a compound created by a condensation reaction.

There is also described herein a method of coating a substrate with a film comprising a low VOC composition described herein and summarized above, the method comprising: coating the substrate with a low VOC conformal coating composition comprising at least one film forming component comprising a water-based carrier; and at least one additive, wherein the at least one film forming component comprises a resin present in an amount sufficient and configured to form the conformal film having a glass transition temperature (T_{g}) less than 25° C., when applied to a substrate at room temperature.

In one embodiment, the coating application is performed using one or more methods selected from atomized or non-atomized spraying spray-coating, needle dispensing, dipping, jetting, blade coating, brush coating, inkjet printing, crosslinking through UV radiation, crosslinking through heating, crosslinking using humidity or combinations thereof.

In one embodiment, the coating is deformable and electrically insulating when being applied on a substrate.

There is also disclosed a coating configured to protect a substrate from unwanted contaminants, the coating comprising: a low VOC composition comprising at least one film forming component comprising a water-based carrier; and at least one additive, wherein the at least one film forming component comprises a resin present in an amount sufficient and configured to form a conformal film having a glass transition temperature (T_{g}) less than 25° C., when applied to the substrate at room temperature.

There is also disclosed a substrate comprising a coating, wherein the coating comprises: a low VOC composition comprising at least one film forming component comprising a water-based carrier; and at least one additive, wherein the at least one film forming component comprises a resin present in an amount sufficient and configured to form a conformal film having a glass transition temperature (T_{g}) less than 25° C. when applied to the substrate at room temperature.

In one embodiment, the substrate comprises an automotive component, a consumer product including a consumer electronic device, or other electronic devices, such as a printed circuit board.

Other embodiments of the invention will be apparent to those skilled in the art from consideration of the specification and practice of the invention disclosed herein. It is intended that the specification and examples be considered as exemplary only, with the true scope of the invention being indicated by the following claims.

What is claimed is:

1. A low VOC composition to protect a substrate from at least one unwanted contaminant, comprising:
at least one film forming component comprising a water-based carrier; and
at least one additive,
wherein the at least one film forming component comprises a resin present in an amount sufficient and configured to form a conformal film having a glass transition temperature (T_{g}) less than 25° C., when applied to a substrate at room temperature.

2. The low VOC composition of claim 1, wherein the conformal film is deformable and electrically insulating when being applied on the substrate.

3. The low VOC composition of claim 1, wherein the at least one additive comprises fillers, plasticizers, initiators, defoamers, surfactants, antioxidants, hydrophobing agents, biocides, leveling agents, substrate wetting agents, crosslinking agents, dyes, pigments, dispersing agents, passivators, adhesion promoters, coalescing agents or solvents, rheology modifiers, UV absorbers or stabilizers, and anti-corrosion agents.

4. The low VOC composition of claim 1, wherein the at least one additive is present in the composition in an amount ranging from 0.001% to 40% by weight.

5. The low VOC composition of claim 3, wherein the fillers comprise functionalized fumed silica, unfunctionalized fumed silica, precipitated silica, silica nanoparticles, alumina nanoparticles, zinc oxide nanoparticles, or cellulose-based particles, and combinations thereof.

6. The low VOC composition of claim 3, wherein the plasticizers comprise a polymeric plasticizer, a benzoate plasticizer, and a phthalate plasticizer.

7. The low VOC composition of claim 6, wherein the benzoate plasticizer comprises diethylene glycol dibenzoate, dipropylene glycol dibenzoate, propylene glycol dibenzoate, and combinations thereof.

8. The low VOC composition of claim 6, wherein the polymeric plasticizer comprises poly[oxy(methyl-1,2-ethanediyl)], alpha-(methylphenyl)-omega-hydroxy, biobased alkyd, and combinations thereof.

9. The low VOC composition of claim 3, wherein the plasticizer comprises hydrogenated cycloaliphatic hydrocarbon resins, trimellitates, high molecular weight orthophthalates, silicone oils, octyl epoxy esters or hydrotreated light naphthenic petroleum distillates, and combinations thereof.

10. The low VOC composition of claim 3, wherein the initiator comprises a difunctional or multifunctional alpha-hydroxyketones, acylphosphine oxides, benzoyl formate, benzophenones, zinc oxide nanoparticles, peroxides, azo compounds, and combinations thereof.

11. The low VOC composition of claim 3, wherein the defoamer comprises a silicone oil, a mineral oil, a vegetable oil, a polar oil, a molecular defoamer, a hydrophobic nanoparticle, an emulsifier, a solvent, and combinations thereof.

12. The low VOC composition of claim 3, wherein the surfactant comprises a non-ionic surfactant, anionic surfactant, cationic surfactant, zwitterionic surfactant, and combinations thereof.

13. The low VOC composition of claim 3, wherein the hydrophobing agent comprises paraffin wax emulsions, modified paraffin waxes, paraffin/polyethylene wax emulsions, silicone resins, and combinations thereof.

14. The low VOC composition of claim 3, wherein the biocide agent comprises an isothiazolinone, formaldehyde-releasing biocides (FA-R), fungicides comprising carbamates, and combinations thereof.

15. The low VOC composition of claim 3, wherein the rheology modifier comprises a hydrophobic modified ethoxylated urethane (HEUR) type thickener, an alkali swellable emulsion, an acrylic copolymer, and combinations thereof.

16. The low VOC composition of claim 3, wherein the leveling agents comprise silicones, liquid polyacrylates, ionic surfactants, non-ionic surfactants, fluorosurfactants, and combinations thereof.

17. The low VOC composition of claim 3, wherein the substrate wetting agent comprises a siloxane, a multifunctional surfactant, a polyglycol ether, a modified polyglycol ether, and combinations thereof.

18. The low VOC composition of claim 3, wherein the dyes comprise a stilbene compound, a distyryl biphenyl derivative, a benzoxazole, and combinations thereof.

19. The low VOC composition of claim 3, wherein the crosslinking agent comprises zinc ammonium carbonate solution, carbodiimide crosslinkers, melamine crosslinkers, aziridine crosslinkers, mono- or multi-functional, aliphatic, glycerol polyglycidyl ether-based crosslinkers, mono- or multi-functional aliphatic epoxies, ethylene glycol diglycidyl ethers, oxazoline reactive polymers, polyols, polyisocyanates, methylacrylamide, a dihydrazide crosslinkers, organofunctional silanes, metal complexes, UV-vulnerable functional monomers, and combinations thereof.

20. The low VOC composition of claim 3, wherein the pigment comprises an organic pigment, an inorganic pigment, and combinations thereof.

21. The low VOC composition of claim 3, wherein the dispersing agent comprises a fatty acid-modified polyester, sodium salt of an acrylic polymer, an ammonium salt of a hydrophobic copolymer, a modified polyacrylate, zwitterionic surfactants, and combinations thereof.

22. The low VOC composition of claim 3, wherein the adhesion promoter comprises a silane, an ethylene copolymer, a hydroxyl functional copolymer, and combinations thereof.

23. The low VOC composition of claim 3, wherein the coalescing agent comprises a glycol ether, an ester alcohol, and combinations thereof.

24. The low VOC composition of claim 3, wherein the UV absorber or stabilizer comprises hydroxy-phenyl-benzo-triazoles, hydroxy-phenyl-triazines, hydroxy-benzophenones, sterically hindered amines, and combinations thereof.

25. The low VOC composition of claim 3, wherein the anti-corrosion agent comprises an organic acid amine complex, a zinc phosphate, and combinations thereof.

26. The low VOC composition of claim 3, wherein the antioxidant comprises a phenolic antioxidant, an amine antioxidant, a thioether antioxidant, a phosphite antioxidant, a lactone, and combinations thereof.

27. The low VOC composition of claim 26, wherein the phenolic antioxidants are selected from benzenepropanoic acid, 3,5-bis(1,1-dimethylethyl)-4-hydroxy-, octadecyl ester; benzenepropanoic acid, 3,5-bis(1,1-dimethylethyl)-4-hydroxy-,2,2-bis[[3-[3,5-bis(1,1-dimethylethyl)-4-hydroxyphenyl]-1-oxopropoxy]methyl]-1,3-propanediyl ester; reaction mass of isomers of: C7-9-alkyl 3-(3,5-di-tert-butyl-4-hydroxyphenyl) propionate; 1,3,5-Triazine-2,4,6(1H,3H,5H)-trione, 1,3,5-tris {[3,5-bis(1,1-dimethylethyl)-4-hydroxyphenyl] methyl}-; benzenepropanoic acid, 3-(1,1-dimethylethyl)-4-hydroxy-5-methyl-, 2,4,8,10-tetraoxaspiro [5.5]undecane-3,9-diylbis(2,2-dimethyl-2,1-ethanediyl) ester; or phenol, 4-methyl-, reaction products with dicyclopentadiene and isobutylene, and combinations thereof.

28. The low VOC composition of claim 26, wherein the amine antioxidants are selected from benzenamine, N-phenyl-, reaction products with 2,4,4-trimethylpentene; 1-Naphthalenamine, N-phenyl-ar-(1,1,3,3-tetramethylbutyl); 4,4′-Dioctyldiphenylamine; other alkylated amines, and combinations thereof.

29. The low VOC composition of claim 26, wherein the thioether antioxidants are selected from propanoic acid, 3-(dodecylthio)-,1,1′-[2,2-bis[[3-(dodecylthio)-1-oxopropoxy]methyl]-1,3-propanediyl] ester; or propanoic acid, 3,3′-thiobis-, 1,1′-ditridecyl ester; and combinations thereof.

30. The low VOC composition of claim 26, wherein the phosphite antioxidants are selected from tris(2,4-di-tert-butylphenyl) phosphite; butylidenebis[2-tert-butyl-5-methyl-p-phenylene]-P,P,P′,P′-tetratridecylbis(phosphine); 12H-Dibenzo[d,g][1,3,2]dioxaphosphocin,2,4,8, 10-tetrakis(1,1-dimethylethyl)-6-[(2-ethylhexyl)oxy]-; and combinations thereof.

31. The low VOC composition of claim 3, wherein the passivators comprise a hydrazide or a triazole, selected from dodecanedioic acid, 1,12-bis[2-(2-hydroxybenzoyphydrazide]; benzenepropanoic acid, 3,5-bis(1,1-dimethylethyl)-4-hydroxy-, 2-[3-[3,5-bis(1, 1-dimethylethyl)-4-hydroxyphenyl]-1-oxopropyl]hydrazide; 1,2,4-Triazole, 2-Hydroxy-N-(1H-1,2,4-triazol-3-yl)benzamide; 1H-Benzotriazole-1-methanamine, N, N-bis(2-ethylhexyl)-ar-methyl-; 1H-1,2,4-Triazole-1-methanamine, N,N-bis(2-ethylhexyl)-; and combinations thereof.

32. The low VOC composition of claim 3, wherein the rheology modifier comprises sodium polyacrylates, polyamide wax, polyethylene wax, hydrogenated castor oils, attapulgite clay, fumed silica, precipitated silica, metal-oxide particles, and combinations thereof.

33. The low VOC composition of claim 3, wherein the adhesion promoter comprises chlorinated polyolefins, cyanoacrylate primers, polyester alkyl ammonium salts, aminofunctional polyethers, maleic anhydride, carboxylated polypropylene, glycidylmethacrylate-functionalized polyolefins, trimethoxyvinylsilane, silanes, and combinations thereof.

34. The low VOC composition of claim 3, wherein the substrate wetting or dispersing agent comprises alkylammonium salts of a polycarboxylic acid, alkylammonium salt of an acidic polymer, salt of unsaturated polyamine amides and acidic polyesters, maleic anhydride functionalized ethylene butyl acrylate copolymer, other ionic or non-ionic surfactants, and combinations thereof.

35. The low VOC composition of claim 3, wherein the tackifier comprises hydrogenated hydrocarbon resins, cycloaliphatic hydrocarbon resins, and combinations thereof.

36. The low VOC composition of claim 1, wherein the conformal film has a thickness ranging from 25 nm to 500 μm.

37. The low VOC composition of claim 1, wherein the at least one film forming component comprising a water-based carrier comprises an aqueous emulsion or an aqueous dispersion.

38. The low VOC composition of claim 37, wherein the aqueous emulsion or the aqueous dispersion comprises water in an amount ranging from 50 to 70% by weight.

39. The low VOC composition of claim 37, wherein the aqueous emulsion or the aqueous dispersion comprises the resin in an amount ranging from 30 to 50% by weight.

40. The low VOC composition of claim 1, wherein the water-based carrier does not comprise any volatile organic solvents and is VOC-free.

41. The low VOC composition of claim 1, wherein the resin is selected from acrylics, styrene-acrylics, silicone, polyurethane, styrene-butadiene, acrylonitrile-butadiene, and combinations thereof.

42. The low VOC composition of claim 1, further comprising an additional resin that has a higher T_{g} than the first resin.

43. The low VOC composition of claim 42, wherein the additional resin has the same or different chemistry than the first resin.

44. The low VOC composition of claim 42, wherein the additional resin comprises an alkyd, vinyl acrylic, or vinyl-acetate ethylene copolymer.

45. The low VOC composition of claim 1, wherein the at least one film forming component comprises a blend of the resin and a self-cross-linking resin.

46. The low VOC composition of claim 3, wherein the composition comprises a plasticizer in an amount of up to 40% by weight.

47. The low VOC composition of claim 1, wherein the composition has a volatile organic content of 100 g/L or less.

48. The low VOC composition of claim 1, wherein the composition has no volatile organic content.

49. The low VOC composition of claim 1, wherein the at least one unwanted contaminant comprises one or more liquids, solids, gases, and combinations thereof.

50. The low VOC composition of claim 1, wherein the at least one unwanted contaminant comprises water, sweat, or other moisture, dirt, dust, electrically conductive metal particles, metal shavings, and other conductive particulate matter and chemicals, and combinations thereof.

51. A method of making a low VOC composition for protecting substrates against at least one unwanted contaminant, the method comprising:
providing a film forming component comprising a water-based carrier; and
combining at least one additive with said film forming component comprising a water-based carrier,
wherein the at least one film forming component comprises a resin present in an amount sufficient and configured to form a conformal film having a glass transition temperature (T_{g}) less than 25° C., when applied to a substrate at room temperature.

52. The method of claim 51, wherein providing the film forming component comprises at least one polymerization step comprising reacting at least one monomer, oligomer or pre-polymer to produce a film forming polymer resin that can be dispersed or suspended in a water-based carrier with at least one additive to form the low VOC composition.

53. The method of claim 52, wherein the monomer, oligomer or prepolymer contains one or multiple functional groups capable of participating in the polymerization reaction.

54. The method of claim 52, where the polymerization step proceeds by addition or condensation polymerization or combinations thereof.

55. The method of claim 52, where the polymerization step occurs after the at least one monomer, oligomer or pre-polymer has been dispersed or suspended in the water-based carrier.

56. The method of claim 52, where the polymerization step produces reaction products that are then dispersed or suspended in the water-based carrier.

57. The method of claim 52, wherein the method produces one or more of the following by-products: water, ammonia, and a compound created by a condensation reaction.

58. A method of coating a substrate, the method comprising:
coating the substrate with a low VOC composition comprising at least one film forming component comprising a water-based carrier; and at least one additive,
wherein the at least one film forming component comprises a resin present in an amount sufficient and configured to form a conformal film having a glass transition temperature (T_{g}) less than 25° C., when applied to a substrate at room temperature.

59. The method of claim 58, wherein the coating application is performed using one or more methods selected from atomized or non-atomized spraying spray-coating, needle dispensing, dipping, jetting, blade coating, brush coating, inkjet printing, crosslinking through UV radiation, crosslinking through heating, crosslinking using humidity or combinations thereof.

60. A coating configured to protect a substrate from unwanted contaminants, the coating comprising:
a low VOC composition comprising at least one film forming component; and at least one additive,
wherein the at least one film forming component comprises a resin present in an amount sufficient and configured to form a conformal film having a glass transition temperature (T_{g}) less than 25° C., when applied to the substrate at room temperature.

61. The coating of claim 60, wherein the at least one unwanted contaminant comprises one or more liquids, solids, gases, and combinations thereof.

62. The coating of claim 60, wherein the at least one unwanted contaminant comprises water, sweat, or other moisture, dirt, dust, electrically conductive metal particles, metal shavings, and other conductive particulate matter and chemicals, and combinations thereof.

63. A substrate comprising a low VOC coating, wherein the low VOC coating comprises:
a low VOC composition comprising at least one film forming component; and at least one additive,
wherein the at least one film forming component comprises a resin present in an amount sufficient and configured to form a conformal film having a glass transition temperature (T_{g}) less than 25° C., when applied to the substrate at room temperature.
